(19) United States
(12) Patent Application Publication
(10) Pub. No.: US 2021/0109130 A1
(43) Pub. Date: Apr. 15, 2021

(54) METHOD AND APPARATUS FOR CONTROLLING A MEASUREMENT DEVICE

(71) Applicant: Rohde & Schwarz GmbH & Co. KG, Munchen (DE)

(72) Inventor: Sven Barthel, Chemnitz (DE)

(21) Appl. No.: 16/599,367

(22) Filed: Oct. 11, 2019

(51) Int. Cl. G01R 13/02

(52) U.S. Cl. CPC G01R 13/029; G01R 13/0272; G01R 13/0245

(57) ABSTRACT

An improved selection of a specific position in a measured signal is provided. For this purpose, a coarse selection of a position is received and subsequently one or more specific events nearby the coarse position are identified. Accordingly, one of the identified events may be selected and precise positioning on the selected event is performed.

### TECHNICAL FIELD

The present invention relates to a method for controlling a measurement device. The present invention further relates to an apparatus for controlling a measuring device.

### BACKGROUND

Also applicable in principle to any measurement of signals dealing with signal waveforms, the present invention and its underlying problem will be hereinafter described in combination with an oscilloscope.

In order to analyze a measured signal, a signal waveform of the measured signal may be displayed on a display, and a user may select a specific position for further analysis. For this purpose, the user has to identify the desired position with high accuracy. However, this selection of a specific position may be limited by multiple parameters such as resolution of the display, accuracy of an input device and the skills of an operator.

Against this background, a problem addressed by the present invention is to provide an improved selection of a specific position of a measured signal. In particular, the present invention aims to provide an improved selection of a specific position of a signal measured by a measuring device.

### SUMMARY

The present invention provides a method and an apparatus for controlling a measurement device is the features of the independent claims. Further advantages embodiments are subject matter of the dependent claims.

According to a first aspect, a method for controlling a measuring device is provided. The method comprises displaying a signal waveform of a measured signal. Further, the method comprises receiving a first input. The first input may specify a first position in the displayed signal waveform. Further, the method comprises identifying a number of one or more predetermined events in the measured signal. In particular, one or more predetermined events are identified in a preset area, wherein the preset area specifies an area with respect to the first position. The identified events may be displayed. In particular, a selection menu for selecting one of the identified events may be provided. The method may further comprise receiving a second input. The second input may specify a selection of one of the identified events.

According to a further aspect, an apparatus for controlling a measuring device is provided. The apparatus comprises a display, an input device and a processing device. The display is configured to display a signal waveform of a measured signal. The input device is configured to receive a first input. The first input may specify a first position in the displayed signal waveform. The processing device is configured to identify one or more predetermined events. In particular, the one or more predetermined events may be identified in a preset area. The preset area may be selected with respect to the first position. The display is further configured to display the identified events. In particular, the display may provide a menu for selecting one of the identified events. The input device is further configured to receive a second input. The second input may specify a selection of one of the displayed identified events.

The present invention is based on the finding that it may be difficult to precisely specify a specific position in a measured signal. In particular, if a relative large segment of a measured signal is provided to a user, it may be rather difficult to select a specific position without zooming the representation of the measured signal. However, zooming the representation of the measured signal may also come with some drawbacks. For example, a zoomed representation may provide only a limited segment of the measured signal. Further to this, zooming the representation may require additional operational steps, and thus, additional time is required.

The present invention therefore takes into account this finding and aims to provide an improved control of a measuring device for precisely and efficiently selecting a specific position of a measurement signal. For this purpose, a user may perform a coarse selection of a desired position. After such a coarse selection is received, an automated analysis of the respective measurement signal is performed in order to identify specific events and related positions in the measured signal. Accordingly, by providing the identified events to a user, a user may select one of the identified events. The corresponding position of the selected event can be used for further operations. For example, related measurement values of such a position may be determined.

The measured signal may be any kind of measured signal, in particular any kind of measured signal sequence. In particular, the measured signal may be a digital signal, i.e. digital data representing the measured signal sequence. For example, the measured signal may be obtained by an analogue-to-digital conversion of a measured analogue signal.

The measured signal may be obtained from a measuring device and stored in a memory. This memory may be any kind of memory such as a random access memory, a non-volatile memory, a hard disk drive or the like. However, any other kind of memory for storing the data of the measured signal may be possible, too.

The measurement signal may be acquired by any kind of measurement device. For example, the measurement signal may be acquired by an oscilloscope or the like. However, any other kind of measurement signal for measuring one or more signal sequences may be also possible.

In order to display the signal waveform of the measured signal, the signal waveform, i.e. a representation of the measured signal sequence may be displayed on a display. For this purpose, any kind of display may be used. For example, the display may be a computer display, e.g. a TFT screen or the like. Furthermore, the display may be a display of the measuring device, which has acquired and stored the measurement signal. The display may be a monochrome or a colored display. The display may comprise a touch-screen for displaying data and receiving user input. However, it is understood that any other kind of a display for providing a representation of the measured signal may be possible, too.

Even though it has been mentioned before only to display a single waveform of a measured signal, it may be also possible to measure two or more signals and to display the signal waveforms of multiple signals on the display. Accordingly, the following operations may be applied to one of the displayed multiple signal waveforms. However, it may be also possible to apply these operations to multiple signal waveforms, in particular to apply the operations to multiple signal waveforms simultaneously.

After a signal waveform of the measured signal is displayed, a user may identify a desired position in the displayed signal waveform. For this purpose, the user may provide an input. This specification of the desired position may be a coarse selection of a position in the displayed waveform. For example, a user may indicate a desired position by a touch or a specific gesture on a touch-screen. Furthermore, a user may specify the position by moving a cursor on the display, which provides the representation of the signal waveform. For example, a user may move around cursor by means of a mouse or any other appropriate input device. In particular, the desired position may be indicated by a mouse click when the cursor is positioned on the desired position of the signal waveform. However, it is understood that any other manner for indicating the desired position, for example by means of keys, joystick or any other appropriate input device may be possible, too.

After receiving the indication of the coarse position by the user input, the measured signal may be analyzed. In particular, the measured signal may be analyzed in a predetermined area. This predetermined area may be selected according to the position of the received user input. Accordingly, a specific segment of the measured signal may be analyzed in order to identify predetermined events in the measured signal.

The predetermined events may be any kind of appropriate events such as rising or falling edges, a specific absolute or relative value of the measured signal, a specific waveform segment or any other appropriate event in the measured signal. For this purpose, the data of the measured signal may be read from a memory storing the measured signal data. Accordingly, the processing device may perform any appropriate analysis in order to identify the predetermined events in a segment of the measured signal according to the specified coarse position.

After identifying one or more events in the measured signal, the positions of the identified events and/or the properties of the identified events may be provided to the user. For example, a selection menu may be generated, wherein this selection menu comprises the identified predetermined events. However, it may be also possible to indicate the identified predetermined events directly on the displayed signal waveform. For example, an indicator may be positioned on the respective positions of the signal waveform. Alternatively, it may be also possible to change a color at the respective positions or to indicate the identified events in any other appropriate manner.

After providing the identified predetermined events in the signal waveform, a user may select one of the identified events. Accordingly, a further input of the user may be received. This further input of the user may be received, for example by the same input device, which has been already used for receiving the coarse selection as mentioned above. For example, a user may indicate a selection by a touch or a specific gesture on a touch-screen, by an appropriate mouse operation or any other kind of input operation on an appropriate input device.

After a selection of the user for one of the provided events has been received, the corresponding position in the measured signal may be set to the position of this characteristic. Accordingly, a precise positioning/selection in the measured signal can be achieved.

Further embodiments of the present invention are subject of the further sub-claims and of the following description, referring to the drawings.

In a possible embodiment, a second position in the measured signal is determined. In particular, the determination of the second position may be performed by the processing device. The second position may relate to a position corresponding to the characteristic, which has been selected by the second input.

In this way, it is possible to precisely identify a position in the measured signal, which corresponds to the respective characteristic. In particular, the position can be determined very precisely, wherein the positioning is not limited by conditions such as a limited resolution of the provided signal waveform, the skills of a user or the like. Furthermore, the positioning can be set very precisely to a specific event without the need of a high zoom level of the displayed signal waveform.

In a possible embodiment, the second position is set to a position of the identified event in the signal waveform automatically, if only a single predetermined event is identified in the signal waveform.

In case that only a single predetermined event is identified in the preset area surrounding the position according to the first input, it can be assumed that this event may be an appropriate position in the displayed signal waveform. Accordingly, by automatically selecting this position, the operation of the selection process can be further simplified.

In a possible embodiment, a size of the preset area is adjustable.

In particular, a horizontal and/or vertical size of the preset area may be adapted. For example, a horizontal size may relate to an X-direction, especially to a period of time. A horizontal direction may relate to a Y-axis, for example to a value of a measured signal such as a voltage or the like. The size of the preset area may be adjusted manually, for example by a user input. Alternatively, the size of the preset area may be adjusted automatically, for example based on settings of the measuring device, measurement parameters such as sampling rate, resolution or any other appropriate parameter.

In a possible embodiment, the predetermined events are identified in an area of the signal waveform before the first position and/or behind the first position. Additionally or alternatively, it may be also possible to identify predetermined events in an area of the signal waveform above the first position and/or below the first position.

The expressions “before” and “behind” of the first position may relate to a horizontal direction, which may be defined as already mentioned above. Accordingly, the expressions “above” and “below” of the first position may relate to a vertical direction, which may be also considered as already specified above. Accordingly, by selecting the preset area in such a manner, the search for the events in the measured signal may be limited to a segment of the measured signal in a period of time before the coarse selection by the first input, and/or a period of time after the coarse selection according to the second input. Furthermore, by setting the preset area in horizontal direction, the search for events in the measured signal may be limited to measurement values, which are higher and/or lower than a value according to the coarse selection specified by the first input. The preset area may be set by absolute values, for example in terms of seconds or milliseconds, volts, millivolts or any other appropriate unit. Furthermore, it may be also possible to specify the preset area in relative terms, for example by a range of 10%, 20% or the like.

In a possible embodiment, the predetermined events may comprise at least one of a rising edge, a falling edge, a signal increasing or decreasing a predetermined level, a peak value or a number of one or more predetermined values.

In general, it may be possible to identify any kind of events in the measured signal. Further to singular events such as a rising or falling edge or a specific value, it may be also possible to consider complex events such as specific signal waveform segments or the like. The events in the measured signal may be events with respect to an absolute value, for example an absolute value of the measured signal, or a relative value, for example a change of the measurement signal of a specific range, for example 10%, 20% or the like.

In a possible embodiment, similar or same events are identified in a single signal waveform when identifying the one or more predetermined events. In other words, the identified events all relate to same or similar properties.

For example, all identified events relate to rising edges or falling edges. Furthermore, the identified events may all relate to positions of the measured signal having a specific value or any other kind of specific characteristic. Alternatively, it may be also possible that multiple different events are identified in a signal waveform.

In a possible embodiment, similar or same events are identified in a plurality of different signal waveforms. In particular, the plurality of different waveforms may relate to multiple waveforms of different measured signals.

Accordingly, the identification of the predetermined events may be applied to multiple measured signal sequences in parallel. For example, it may be possible to identify rising edges or falling edges in all of the plurality of measured signals, or to identify any other kind of predetermined events in multiple signal sequences.

In a possible embodiment, an analysis of the measured signal may be applied based on the determined second position.

Accordingly, the analysis may be applied to the measured signal at the position indicated by the second position related to the selected characteristic. Since the second position is determined according to a specific event in the measures signal, the point in time and/or the value of the measures signal is set very precisely and thus very accurate results of the analysis can be expected.

With the present invention it is therefore possible to identify a specific position in a measured signal in a very easy and efficient manner. In particular, since a user only has to identify a coarse positioning in a signal waveform, and subsequently the positioning is performed automatically by identifying specific events in the measured signal, a very precise positioning can be achieved. In case that more than one specific event is identified in an area surrounding the coarse selection of a user, the user may select one of the identified events and the positioning is automatically performed for the selected event. Thus, an accurate positioning for a further analysis can be achieved, and the results of such an analysis can be improved. In particular, it is not necessary to apply a zooming of the displayed signal waveform for the precise positioning. Thus, the required time for precisely positioning and selecting a specific event in a measured signal can be reduced.

### BRIEF DESCRIPTION OF THE DRAWINGS

For a more complete understanding of the present invention and advantages thereof, reference is now made to the following description taking in conjunction with the accompanying drawings. The invention is explained in more detail below using exemplary embodiments, which are specified in the schematic figures and the drawings, in which:

FIG. 1: shows a block diagram of an apparatus according to an embodiment;

FIG. 2: shows a diagram illustrating a selection of a position in a measured signal according to an embodiment;

FIG. 3: shows a diagram illustrating a selection of a position in a signal waveform according to a further embodiment;

FIG. 4: shows a diagram illustrating a representation of multiple events embodiments in a signal waveform according to an embodiment;

FIG. 5: shows a schematic illustration for providing multiple identified events in signal waveforms according to an embodiment; and

FIG. 6: shows a flow diagram illustrating a method according to an embodiment.

The appended drawings are intended to provide further understanding of the embodiments of the invention. They illustrate embodiments and, in conjunction with the description, help to explain principles and concepts of the invention. Other embodiments and many of the advantages mentioned become apparent in view of the drawings. The elements in the drawings are not necessarily shown in scale.

In the drawings, same, functionally equivalent and identical operating elements, features and components are provided with same reference signs in each case, unless stated otherwise.

### DETAILED DESCRIPTION OF THE DRAWINGS

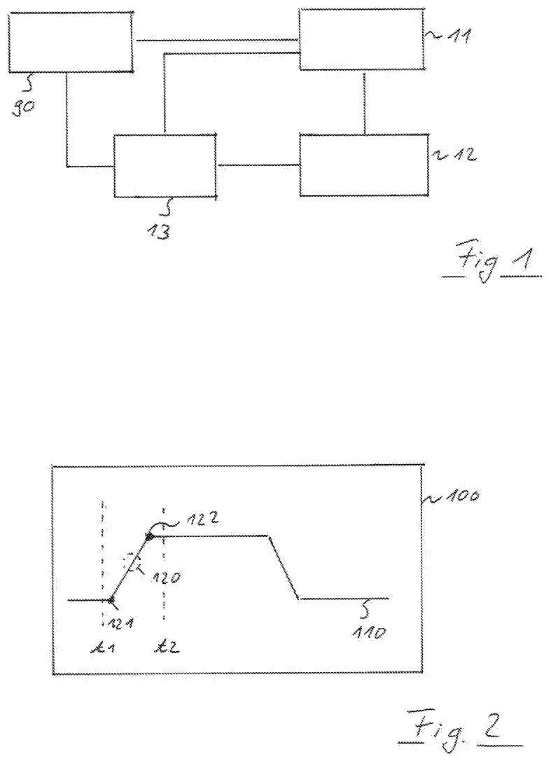

FIG. 1 shows a block diagram of a measurement system with an apparatus for controlling a measuring device 90 according to an embodiment. Measuring device 90 may measure a device under test (not shown) or acquire measurement data from a measurement source. The acquired measurement data may be stored in a memory. For this purpose, the measurement data may be acquired in digital form. For example, an analogue signal may be converted to digital data by an analogue-to-digital converter, and the respective digital data may be stored in a memory. Further, the measurement data may be processed and a representation of the acquired measurement data may be displayed on a display 11.

The measurement and data acquisition of measurement device 90 is not limited to a measurement of only a signal source. Moreover, it may be possible that measuring device 90 may acquire measurement data by a number of one or more measurement channels. Accordingly, the representation, which is displayed on a display 11, may comprise a corresponding number of signal waveforms.

If more than one signal waveform is displayed on a display 11, the individual signal waveforms may be arranged in any appropriate manner. For example, the individual signal waveforms may be displayed in separate areas, for example in an arrangement, wherein the individual signal waveforms are displayed above each other. Alternatively, the individual signal waveforms may be also overlaid in a common diagram. However, it is understood that any other appropriate manner for displaying the signal waveforms may be possible, too.

If a user wants to specify a specific position in the representation of the measurement signals in the signal waveform, the user has to identify the desired position. Since a very precise selection of a specific position in a signal waveform is very difficult and limited by the resolution of the display for displaying the signal waveform, the user has to apply one or more zooming operations in order to zoom in the signal waveform for a precise selection. In order to avoid the need for such a zooming and to assist the user by precisely specifying a specific position in the signal waveform, an enhanced approach for selecting a specific position is provided.

For this purpose, a user may perform a coarse first selection of a desired position. This first coarse selection may be performed based on an overview of the signal waveform of the acquired measured signal, which is provided on display 11. For this purpose, the coarse identification of a desired position may be received by an input device 12.

Input device 12 may be any kind of appropriate device for receiving the selection of the user for identifying a desired position in the signal waveform. For example, input device 12 may a device for receiving a touch or a gesture from a user. For this purpose, display 11 and input device 12 may be realized by a touch-screen or the like. Further, it may be also possible to receive the selection of the user by any other appropriate input device. For example, input device 11 may be a mouse such as a computer mouse. Accordingly, a user may move a cursor around in order to specify a desired position and indicate the selection by mouse-click. Alternatively, it may be also possible that the user may specify the desired position in any other appropriate manner. For example, the user may use a keyboard, a joystick, a trackball or the like.

After are user has identified a coarse first position at the signal waveform displayed on a display 11, this first position may be used as a basis for assisting the user in order to achieve a more precise selection of a specific position in the signal waveform.

The specified first coarse position, which is obtained from the user by input device 12, may be provided to a processing device 13. Processing device 13 may analyze the surrounding of the specified first position in the signal waveform, in order to identify specific events of interest in the surrounding of the indicated first position. The identified events may be provided to the user, and the user may select one of the identified events. Accordingly, a precise selection of the measured data at the position of the selected event may be applied. Accordingly, the further analysis of the measured data may be performed based on this precise selection.

In the following, the identification of the events and the related operations are described in more detail.

After a first input for specifying a coarse position in the displayed waveform has been received by input device 12, the received first input may be provided to processing device 13. Processing device 13 may perform a search for a number of one or more predetermined events in the measured signal sequence in an area surrounding the received first position. The surrounding the first position may be an area, which is limited to a predetermined period of time before and/or after the point of time, which relates to the received first position. Additionally or alternatively, the area may be an area, which is limited to measurement values in a predetermined arrange above or below the value according to the received first position, i.e. the value being higher or lower than a value of the measurement signal at the specified first position.

Processing device 13 may search for any kind of predetermined events in the respective area with respect to the received first position. For example, rising edges, falling edges, measurement values with a specific value or within a specific range, a maximum, a minimum, signal sequences with a predetermined slope or any other characteristic event may be identified. Further to this, it may be also possible to identify predetermined sequences in the measured signal. However, it is understood that the search for predetermined events in the measured signal is not limited to the mentioned examples. Moreover, any other kind of events may be also identified.

After identifying one or more predetermined events in the area with respect to the received first position, the identified events may be provided to the user, and a user may select one of the provided events. For this purpose, processing device 13 may generate a selection menu, and the generated selection menu may be displayed on display 11. Input device 11 may receive a user input for specifying a selection of one of the events provided by the displayed selection menu. Accordingly, processing device 13 may apply a selection of a position at the measured signal sequence corresponding to the position of the selected characteristic.

The identified events in the area surrounding the first position may be provided to the user in any appropriate manner. As already mentioned above, a selection menu may be generated and displayed on display 12. Furthermore, it may be also possible to indicate the identified events directly on the displayed signal waveform, which is displayed on display 12. For example, the identified events may be highlighted. For this purpose, a color of the signal waveform for the background may be changed at the respective positions, a selection item may be displayed on the respective positions, or any other appropriate scheme for indicating the identified events may be possible. Accordingly, a user may select one of the identified events by input device 12. For example, a user may touch on touch-screen, move a mouse-cursor and click the respective position or perform any other kind of selecting one of the displayed events.

After receiving the selection of the user for one of the displayed events, processing device 13 may determine thee related point in time and/or a related measurement value. Thus, any kind of further processing may be applied based on the identified parameters. For example, an analysis of the measured signal may be performed based on the identified parameters relating to the selected position. For example, the selected position may relate to a starting point or an ending point for analyzing the measured signal. However, any other approach for analyzing or processing the measured signals based on the selection may be also possible.

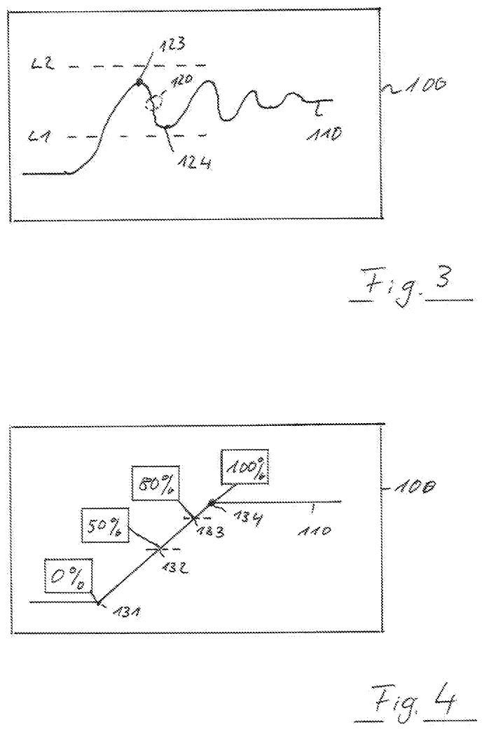

FIG. 2 shows a diagram illustrating the selection process according to a first embodiment. FIG. 2 shows a representation 100 of a signal waveform 110 representing a measurement sequence of measured data. For example, a user may indicate a first position 120. For example, the user may move a cursor to this position or apply a touch on the touch-screen at this position. Accordingly, after input device 12 has received this first input for specifying position 120, processing device 13 may search for predetermined events within a preset range. For example, the measurement data may be analyzed between a first point in time t1 and a second point in time t2. During this search processing device 13 may identify a starting point 121 of a rising edge and an ending point 122 of the rising edge. Accordingly, these positions may be indicated in representation 100. Accordingly, the user may select one of the indicated events 121, 122.

FIG. 3 shows a further representation 100 of a signal waveform 110. As already described above, a user may specify a first position 120. Accordingly, after receiving the input for specifying the first position 120, processing device 130 may search for predetermined events in a range between a minimum value L1 and a maximum value L2. For example, processing device 13 may identify a maximum 123 and a (local) minimum 124. Accordingly, these identified events may be indicated in representation 110.

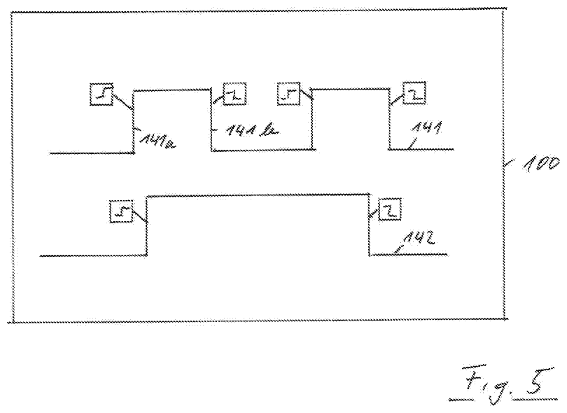

FIG. 4 shows a further example for identifying predetermined events in a representation of a measurement sequence. As can be seen in FIG. 4, the displayed signal waveform 110 comprises a rising edge. In particular, the measured signal sequence rises from a minimum value to a maximum value within a specific period of time. Accordingly, if processing device 13 searches for predetermined events within an area comprising this rising edge, it may be possible to identify positions of multiple different events. For example, it may be possible to identify a position 131, at which the measured values start rising, for example from zero percent to higher values. Furthermore, it may be possible to identify the position 134 at which the measured signal reaches the highest value, for example 100%. Furthermore, it may be possible to determine further positions at which the measured signal reaches predetermined values. For example, the measured signal may reach a value of 50% at a position 132, and reach a value of, for example 80%, at position 133. However, it is understood, that any other level or value for specifying an event may be also possible. For example, it may be possible to identify positions in the measured signal having a level of 10%, 20%, 30%, . . . , 70%, 80%, 90%, 95% or 100%. Accordingly, the identified positions may be provided on display 11. Thus, a user may select a desired position. In this way, a precise positioning at a specific event of the measured signal can be achieved.

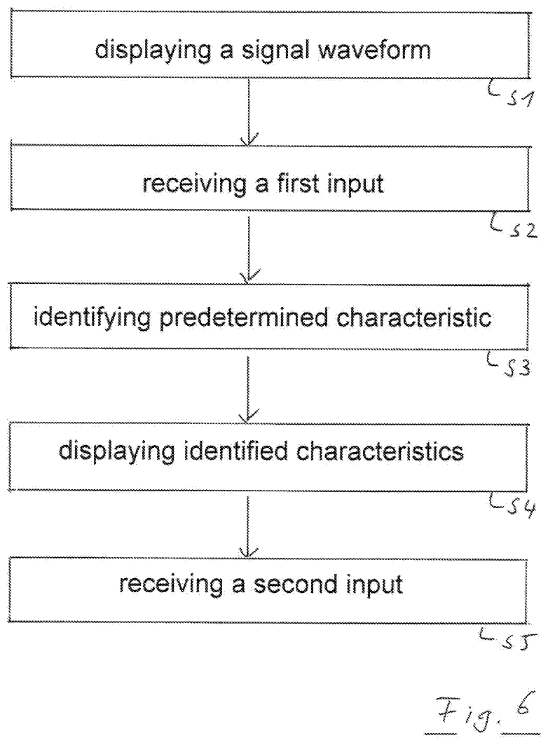

FIG. 5 shows a further schematic representation of signal waveforms according to an embodiment. As can be seen in this example, it may be even possible to provide multiple signal waveforms in a common representation on display 11. Accordingly, it may be possible to identify events in one or more, or even all of the displayed signal waveforms. In particular, it may be possible, for example, to identify positions of events in all displayed signal waveforms based on an input received in connection with one of the displayed signal waveforms. For example, if a first input is received in connection with a first signal waveform 141, it may be possible to analyze measurement data of all signal waveforms displayed in the representation 100. Accordingly, it may be possible to identify, for example, rising edges in both, the first signal waveform 141 and the second signal waveform 142. For example, the identification of events may be limited to a period of time in connection with the first input for specifying a first position of the signal waveform 141.

However, any kind of approach for identifying events in one or more signal waveforms 141, 142 may be possible. For example, it may be possible to analyze a predetermined area relating to the measured signal of a first signal 141. Accordingly, if one or more events are identified in this area, it may be possible to search the further displayed signal waveforms 142 for events, which are similar or even the same the events identified in the area, which is used for analyzing the first signal waveform 141. For example, if a rising edge 141a is identified in the respective area of the first signal waveform 141, it may be possible to search only for rising edges in the second signal waveform 142. Alternatively, if only a falling edge 141b is identified in the respective area of the first signal waveform 142, it may be possible to search only for falling edges in the second signal waveform 142.

In an alternative example, it may be possible to consider only a single waveform and to search the whole section of the displayed signal waveform for events elements, which are identified in an area relating to the identified first position. For example, if in an area according to the identified first position, a rising edge is identified, the whole signal waveform, in particular the whole section of the displayed signal waveform for this signal may be searched for further rising edges.

However, it is understood that any other approach for identifying events elements in one or more signal waveforms and for providing an appropriate selection for selecting one of the identified events may be also possible.

FIG. 6 shows a flow diagram illustrating a method for controlling a measuring device according to an embodiment. The method may perform any kind of step as already described above in connection with the apparatus for controlling the measuring device. Accordingly, the above-mentioned apparatus may perform any operation as will be described in the following.

In a step S1, a signal waveform of a measured signal is displayed. The signal waveform may be displayed, for example on a display 11.

In a step S2, a first input is received. The first input may specify a first position in the displayed signal waveform. In particular, the first input may be received by an input device 12.

In a step S3, one or more predetermined events may be identified in the measured signal. In particular, the predetermined events may be identified in a preset area with respect to the first position. The analysis of the measured signal for identifying predetermined events may be performed, for example by processing device 13.

In step S4, the identified events may be displayed. In particular, the identified events may be displayed on a display 11. For example, the identified events may be displayed in a selection menu. Alternatively, the identified events may be directly indicated in the displayed signal waveform. However, any other appropriate scheme for providing the identified events may be also possible.

In step S5, a second input is received. The second input may specify one of the displayed identified events.

After receiving a second input for selecting one of the displayed events, a second position in the displayed waveform may be determined. In particular, the second position may relate to a position of the event selected by the second input.

The second position may be automatically set to a position of the identified event in the identified signal, if only a single predetermined event is identified in the signal waveform. In particular, the size of the preset area may be adjustable. For example, the size may be adjustable by a manual input of a user. Alternatively, the size of the area may be dynamically adapted depending on predetermined parameters. For example, the size of the area may be set depending on the range or scale used for displaying the signal waveform on the display.

The predetermined events in the signal waveform may be identified in an area of the signal waveform before the first position and/or behind the first position. Additionally or alternatively, the predetermined events may be identified in an area above the first position and/or below the first position.

In particular, the predetermined events may comprise a rising edge, a falling edge, a signal increasing or decreasing a predetermined level, a signal reaching a specific level, a peak value of the signal or a number of one or more predetermined values in the measured signal.

In particular, the method may identify one or more similar or same events in a single signal waveform.

The method may also comprise identifying similar or same events in a plurality of different signal waveforms.

Alternatively, it may be also possible to identify multiple different predetermined events in a single signal waveform.

The method may further comprise an analysis of the measured signal based on the determined second position.

Summarizing, the present invention relates to an improved selection of a specific position in a measured signal. For this purpose, a coarse selection of a position is received and subsequently one or more specific events nearby the coarse position are identified. Accordingly, one of the identified events may be selected and precise positioning on the selected event is performed.

Although specific embodiments have been illustrated and described herein, it will be appreciated by those of ordinary skill in the art that a variety of alternate and/or equivalent implementations exist. It should be appreciated that the exemplary embodiment or exemplary embodiments are only examples, and are not intended to limit the scope, applicability, or configuration in any way. Rather, the foregoing summary and detailed description will provide those skilled in the art with a convenient road map for implementing at least one exemplary embodiment, it being understood that various changes may be made in the function and arrangement of elements described in an exemplary embodiment without departing from the scope as set forth in the appended claims and their legal equivalents. Generally, this application is intended to cover any adaptations or variations of the specific embodiments discussed herein.

In the foregoing detailed description, various features are grouped together in one or more examples or examples for the purpose of streamlining the disclosure. It is understood that the above description is intended to be illustrative, and not restrictive. It is intended to cover all alternatives, modifications and equivalents as may be included within the scope of the invention. Many other examples will be apparent to one skilled in the art upon re-viewing the above specification.

Specific nomenclature used in the foregoing specification is used to provide a thorough understanding of the invention. However, it will be apparent to one skilled in the art in light of the specification provided herein that the specific details are not required in order to practice the invention. Thus, the foregoing descriptions of specific embodiments of the present invention are presented for purposes of illustration and description. They are not in-tended to be exhaustive or to limit the invention to the precise forms disclosed; obviously many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated. Throughout the specification, the terms “including” and “in which” are used as the plain-English equivalents of the respective terms “comprising” and “wherein,” respectively. Moreover, the terms “first,” “second,” and “third,” etc., are used merely as labels, and are not intended to impose numerical requirements on or to establish a certain ranking of importance of their objects.

### LIST OF REFERENCE SIGNS

11 display
12 input device
13 processing device
90 measurement device
100 graphical representation
110, 141, 142 signal waveform
120 cursor
121, 122, 123, 124 positions of events
S1, S2, S3, S4, S5 method steps

1. A method for controlling a measurement device, the method comprising:
displaying a signal waveform of a measured signal;
receiving a first input for specifying a first position in the displayed signal waveform;
identifying one or more predetermined events in a preset area with respect to the first position;
displaying the identified events; and
receiving a second input for selecting one of the displayed identified events.

2. The method of claim 1, comprising determining a second position in the displayed signal waveform, wherein the second position relates to a position of the event which is selected by the second input.

3. The method of claim 2, wherein the second position is set automatically to a position of the identified event in the signal waveform, if only a single predetermined event is identified in the signal waveform.

4. The method of claim 1, wherein a size of the preset area is adjustable.

5. The method of claim 1, wherein the predetermined events are identified in an preset area of the signal waveform before the first position, behind the first position, above the first position and/or below the first position

6. The method of claim 1, wherein the predetermined events comprises at least one of a rising edge, a falling edge, a signal increasing or decreasing a predetermined level, a peak value or a number of one or more predetermined values.

7. The method of claim 1, wherein the identifying one or more predetermined events comprises identifying similar events in a single signal waveform.

8. The method of claim 1, wherein the identifying one or more predetermined events comprises identifying similar events in a plurality of different signal waveforms.

9. The method of claim 1, wherein the identifying one or more predetermined events comprises identifying multiple different predetermined events in the single signal waveform.

10. The method of claim 2, further comprising applying an analysis of the measured signal based on the determined second position.

11. An apparatus for controlling a measurement device, comprising:
a display for displaying a signal waveform of a measured signal;
an input device for receiving a first input for specifying a first position in the displayed signal waveform; and
a processing device for identifying one or more predetermined events in a preset area with respect to the first position;
wherein the display is configured to display the identified events; and
the input device is configured to receive a second input for selecting one of the displayed identified events.

12. The apparatus of claim 11, wherein the processing device is configured to determine a second position in the displayed signal waveform, wherein the second position relates to a position of the event selected by the second input.

13. The apparatus of claim 12, wherein the processing device is configured to automatically set the second position to a position of the identified event in the signal waveform, if only a single predetermined event is identified in the signal waveform.

14. The apparatus of claim 11, wherein a size of the preset area is adjustable.

15. The apparatus of claim 11, wherein the predetermined events are identified in the preset area of the signal waveform before the first position, behind the first position, above the first position and/or below the first position

16. The apparatus of claim 11, wherein the predetermined events comprise at least one of a rising edge, a falling edge, a signal increasing or decreasing a predetermined level or a peak value, a number of one or more predetermined values.

17. The apparatus of claim 11, wherein the processing device is configured to identify similar events in a single signal waveform.

18. The apparatus of claim 11, wherein the processing device is configured to identify similar events in a plurality of different signal waveforms.

19. The apparatus of claim 11, wherein the processing device is configured to identify multiple different predetermined events in the single signal waveform.

20. The apparatus of claim 12, comprising a measurement device for analyzing the measured signal based on the determined second position.
